(19) United States
(12) Patent Application Publication
(10) Pub. No.: US 2009/0122472 A1
(43) Pub. Date: May 14, 2009

(54) Multimedia Device

(75) Inventor: Chun-Ting Wu, Taipei City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: LITE-ON IT CORPORATION, Taipei City (TW)

(21) Appl. No.: 12/212,992

(22) Filed: Sep. 18, 2008

(30) Foreign Application Priority Data
Nov. 13, 2007 (CN) 200710168144.8

(51) Int. Cl. H02B 1/00; H05K 5/03; H04M 1/02

(52) U.S. Cl. 361/600; 455/575.4

(57) ABSTRACT

The present invention discloses a multimedia device, which comprises: a body, a sliding member, which is movably disposed on the body, and a screen, which is rotatable for being disposed on the sliding member, wherein while the sliding member is moved correspondingly to the body, the screen is rotated relatively to the sliding member so as to generate an angle between the screen and the sliding member, thus it is convenient to a user for seeing the screen.

### BACKGROUND OF THE INVENTION

1. Field of the Invention

The present invention generally relates to a multimedia device, more particularly to a multimedia device being capable of adjusting an angle between a screen and a sliding member thereof.

2. Description of the Prior Art

Regular multimedia devices, such as mobile phone, PDA, GPS, laptop, digital camera, etc., are always with buttons and power switches, which may be uncovered and therefore caused damage by collision, long term pressing, etc., so as a type of mobile phone with a sliding cover is developed. Wherein a screen is disposed at the sliding cover, which is capable of covering and protecting the buttons and the power switch as well. On the other hand, the visual effect for the appearance of the mobile phone may be better.

However, because of the screen being installed on the sliding cover, and therefore the screen can be moved with the sliding cover, but the screen is still fixed at the sliding cover. That is, the display surface of the screen is parallel to the surface of the body of the multimedia device, so that the display surface can not be adjusted in angle. Thus, while the user wishes to clearly see the screen, the eyes of the user must be above the multimedia device, or the whole multimedia device must be moved to let the screen be in front of the user.

Different multimedia devices have their own dimensions. Therefore an oversized volume or a wrong position to not easily see the screen may cause inconvenience to the user.

Therefore, how to figure out the disadvantages of prior arts is an important issue to the skilled people in the related field.

### SUMMARY OF THE INVENTION

The primary objective of the present invention is to provide a multimedia device, wherein an angle between a screen and a sliding member of the multimedia device is generated while the screen is moved with the movement of the sliding member.

The present invention discloses a multimedia device, which comprises: a body, a sliding member, which is movably disposed on the body, and a screen, which is rotatable for being disposed on the sliding member, wherein while the sliding member is moved correspondingly to the body, the screen is rotated relatively to the sliding member.

Other and further features, advantages, and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a schematic 3-D assembly view of the multimedia device of the present invention;

FIG. 2 illustrates a schematic 3-D exploded view of the multimedia device of the present invention;

FIG. 3 illustrates a schematic side view of the multimedia device in a close state of the present invention; and

FIG. 4 illustrates a schematic side view of the multimedia device in an open state of the present invention.

### DETAILED DESCRIPTION OF THE INVENTION

Following preferred embodiments and figures will be described in detail so as to approach aforesaid object.

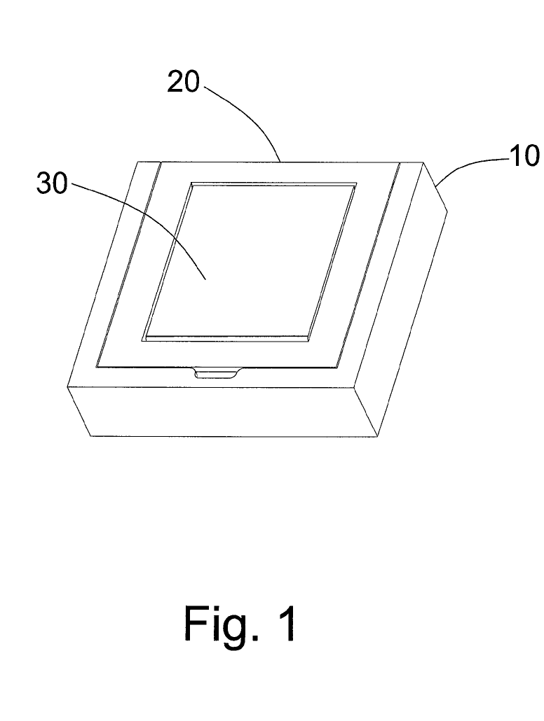

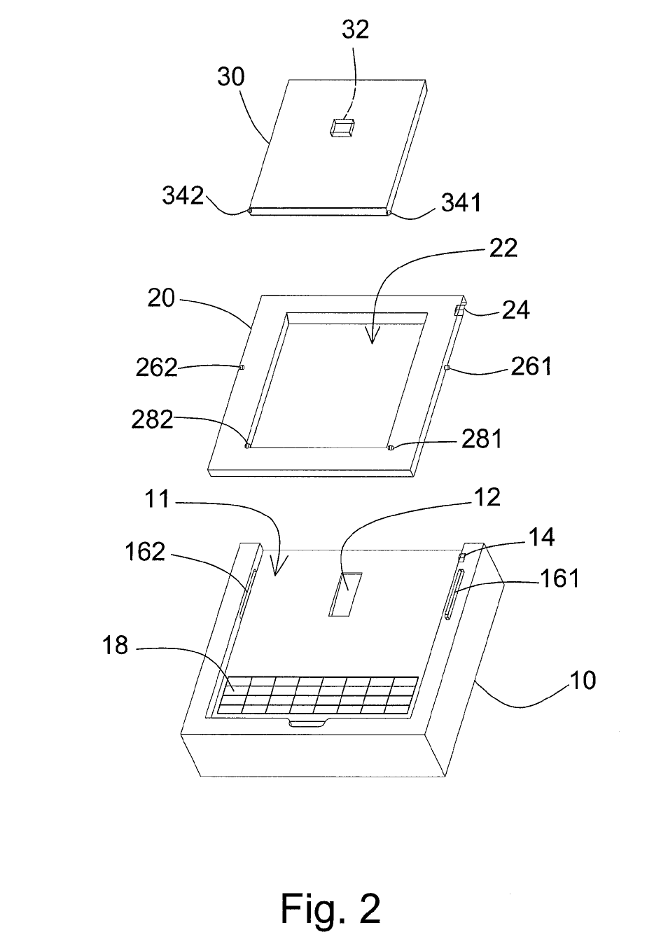

With reference to FIG. 1 and FIG. 2, a schematic 3-D assembly view of the multimedia device of the present invention and a schematic 3-D exploded view of the multimedia device of the present invention are shown.

The preferred embodiment of the multimedia device of the present invention includes a body 10, a sliding member 20, which is movably disposed on the body 10, and a screen 30, which is rotatable for being disposed on the sliding member 20, wherein while the sliding member 20 is moved correspondingly to the body 10, the screen 30 is rotated relatively to the sliding member 20.

According to the preferred embodiment, a reserving section 11 is disposed on the body 10, and two sides of the reserving section 11 are disposed two slideways 161 and 162 respectively. A power switch 14, a bevel slot 12 and a plurality of buttons 18 are disposed on the reserving section 11. The sliding member 20 is disposed in the reserving section 11, and two sides of the sliding member 20 respectively have two protruding columns 261 and 262, which correspond to the two slideways 161 and 162 disposed at the two sides of the reserving section 11. The protruding columns 261 and 262 are respectively moved in the slideways 161 and 162 while the sliding member 20 is moved.

For the preferred embodiment, the sliding member 20 further has a hollow section 22, which two sides respectively have two spindle slots 281 and 282. The screen 30 is disposed in the hollow section 22 of the sliding member 20, and two sides of the screen 30 respectively have two spindles 341 and 342, which are disposed in the spindle slots 281 and 282 so as to rotate the screen correspondingly to the sliding member. Besides, the bottom of the screen 30 has a guiding member 32, which is disposed in the bevel slot 12 of the body 10. The bottom of the sliding member 20 has a power slot 24 corresponding to the power switch 14 of the body 10.

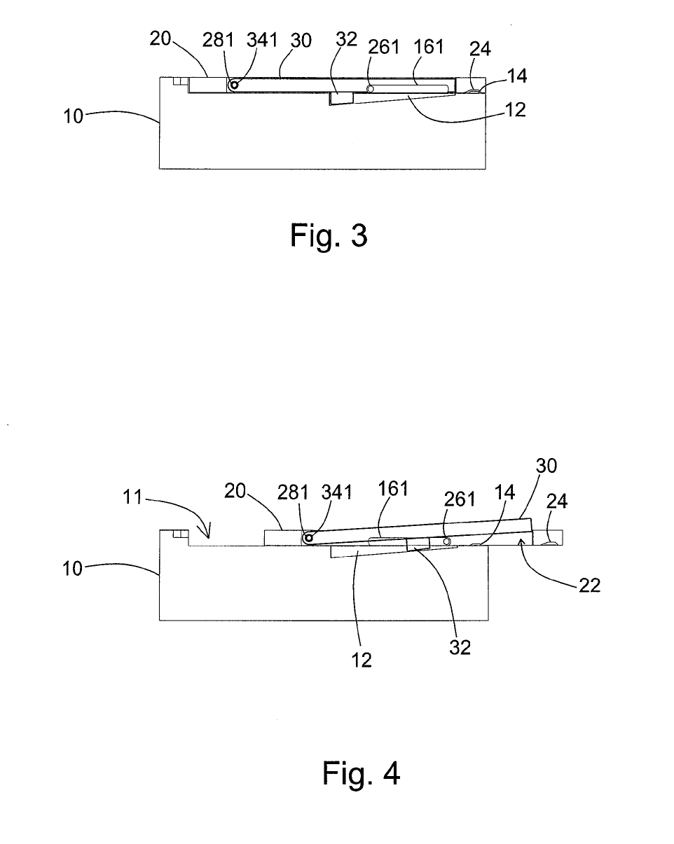

With reference to FIG. 3, a schematic side view of the multimedia device in a close state of the present invention is shown.

For the preferred embodiment, before the multimedia device is completely opened, the sliding member 20 is totally located in the reserving section 11 of the body 10, and the power switch 14 is accommodated in the power slot 24 below the sliding member 20, so that the power switch 14 may not be pressed to start. Further, the guiding member 32 at the bottom of the screen 30 is disposed at the lowest location of the bevel slot 122 in order to maintain the screen 30 in a level state before the multimedia device is opened.

With reference to FIG. 4, a schematic side view of the multimedia device in an open state of the present invention is shown.

Pushing the sliding member 20 is to start up the multimedia device. Due to the guidance of the two protruding columns 261 and 261 disposed at the two sides of the sliding member 20 and the slideways 161 and 162 located at the two sides of the reserving section 11, the sliding member 20 moves horizontally so as to let the protruding columns 261 and 262 be moved from the two ends of the slideways 161 and 162 to another two ends of the slideways 161 and 162 respectively. Because of the pushed sliding member 20, the guiding member 32 at the bottom of the screen 30 is moved from the lowest location to a higher location of the bevel slot 12 of the body 10 so as to rotate the screen 30 an angle around the spindles 341 and 342.

Besides, while the sliding member 20 moves along the slideways 161 and 162, the power switch 14 is moved out from the power slot 24 below the sliding member 20 and continuously pressed by the surface of the bottom of the sliding member 20, so that the sliding member 20 can be in the state of movement and start up the multimedia device simultaneously.

Equally, while turning off the multimedia device is requested, all the sliding member 20 can do is only back to the original position, then the power switch 14 may be again accommodated in the power slot 24 below the sliding member 20 without pressing, and the multimedia device is turned off. On the other hand, the guiding member 32 goes back to the lowest location of the bevel slot 122 as well, and thus the sliding member 20 and the screen 30 may completely be accommodated in the reserving section 11 of the body 11, as shown in FIG. 3.

According to the preferred embodiment, a user may push the sliding member to open the screen and start up the multimedia device simultaneously in order to directly operate the multimedia device via the buttons. Further, due to the bevel slot, the screen may move up along the bevel slot to form an angle for the best view angle of the user while the sliding member is pushed by the user. After usage, the sliding member can be pushed inward, the power switch may turn off the multimedia device automatically, and the screen may be back to the original position following with the movement of the sliding member, the buttons on the body are also disappeared so as to make that the multimedia device seems an integrated product.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A multimedia device comprising:
a body;
a sliding member, which is movably disposed on the body; and
a screen, which is rotatable for being disposed on the sliding member;
wherein while the sliding member is moved correspondingly to the body, the screen is rotated relatively to the sliding member.

2. The multimedia device according to claim 1, wherein the body has a reserving section, and the sliding member is disposed in the reserving section.

3. The multimedia device according to claim 2, wherein each of two sides of the reserving section has a slideway, each of two sides of the sliding member has a protruding column, which corresponds to the slideway and moves in the slideway.

4. The multimedia device according to claim 1, wherein the body has a bevel slot, the bottom of the screen has a guiding member, which moves from the lower location to the higher location of the bevel slot while the sliding member moves to open.

5. The multimedia device according to claim 1, wherein the sliding member has a hollow section, and the screen is disposed in the hollow section.

6. The multimedia device according to claim 5, wherein each of two sides of the hollow section has a spindle slot, each of two sides of the screen has a spindle, which is disposed in the spindle slot so as to rotate the screen correspondingly to the sliding member.

7. The multimedia device according to claim 1, wherein the body has a power switch, the bottom of the sliding member has a power slot corresponding to the power switch, the power switch is accommodated in the power slot while the sliding member is closed, the power switch is moved out from the power slot while the sliding member is opened.
